(19) United States
(12) Patent Application Publication
(10) Pub. No.: US 2015/0296643 A1
(43) Pub. Date: Oct. 15, 2015

(54) PROTECTION DEVICE FOR AN ELECTRONIC DEVICE

(71) Applicants: HONG FU JIN PRECISION INDUSTRY (ShenZhen) CO., LTD, Shenzhen (CN); HON HAI PRECISION INDUSTRY CO., LTD., New Taipei (TW)

(72) Inventors: MING-CHANG LEE, New Taipei (TW); HAI LIU, Shenzhen (CN)

(21) Appl. No.: 14/610,733

(22) Filed: Jan. 30, 2015

(30) Foreign Application Priority Data
Apr. 11, 2014 (CN) 201410144361.3

(51) Int. Cl. H05K 5/02; H05K 5/03

(52) U.S. Cl. CPC H05K 5/0234; H05K 5/03

(57) ABSTRACT

A protection device includes a receiving portion capable of receiving an electronic device therein and a cover pivotally connected to one side of the receiving portion for opening or covering the receiving portion. The cover includes a first reinforcing member, two second reinforcing members symmetrically located at two opposite sides of the first reinforcing member, two third reinforcing members symmetrically located at opposite sides of the second reinforcing members, two symmetrical fourth reinforcing members, and a fifth reinforcing member located between the two fourth reinforcing members. The first, second, third, fourth and fifth reinforcing members are foldably connected to each other. The first reinforcing member is folded toward an outer side of the receiving portion relative to the fifth reinforcing member and is attached to the second reinforcing member, the cover is rotated to allow the first reinforcing member to abut against the back of the receiving portion.

### FIELD

The subject matter herein generally relates to a protection device for an electronic device.

### BACKGROUND

Electronic devices are often used with a protection device to protect the device from damage or shock. The protection device can be a single case or a complex cover.

### BRIEF DESCRIPTION OF THE DRAWINGS

Implementations of the present technology will now be described, by way of example only, with reference to the figures.

FIG. 1 is an isometric view of an embodiment of a protection device and an electronic device, wherein the protection device includes a receiving portion and a cover portion.

FIG. 2 is an assembled, isometric view of FIG. 1, showing the cover portion covering the receiving portion.

FIG. 3 is a cross-sectional view along line III-III of FIG. 1.

FIG. 4 is an assembled, isometric view of FIG. 1, showing the cover portion folded along fold lines and supporting the receiving portion in a first configuration.

FIG. 5 is similar to FIG. 4, but viewed from another aspect.

FIG. 6 is an assembled, isometric view of FIG. 1, but the cover portion folded along fold lines and supporting the receiving portion in a second configuration.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiment described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure is describes a protection device for holding and supporting an electronic device conveniently.

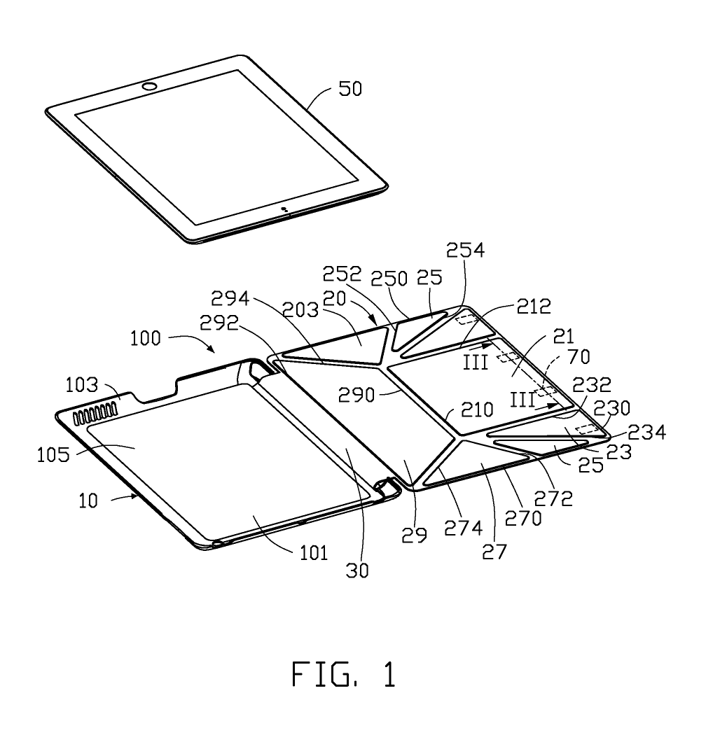

FIG. 1 illustrates an embodiment of a protection device 100. The protection device 100 includes a receiving portion 10 and a cover portion 20 pivotally connected to the receiving portion 10. In this embodiment, the cover portion 20 is pivotally connected to the receiving portion 10 by a flexible rubber strip 30.

The receiving portion 10 includes a substantially rectangular base plate 101 and a peripheral edge 103 extending from edges of the base plate 101. The base plate 101 and the peripheral edge 103 define a receiving space 105 for holding an electronic device 50. In the embodiment, the electronic device is a handheld device, such as a mobile phone. A first edge of the flexible rubber strip 30 is fixed to the base plate 101. A second edge of the flexible rubber strip 30, opposite and parallel to the first edge is connected to the cover portion 20. In this embodiment, the receiving portion 10 is a hard shell, made of, for example, plastic, carbon fiber or glass fiber.

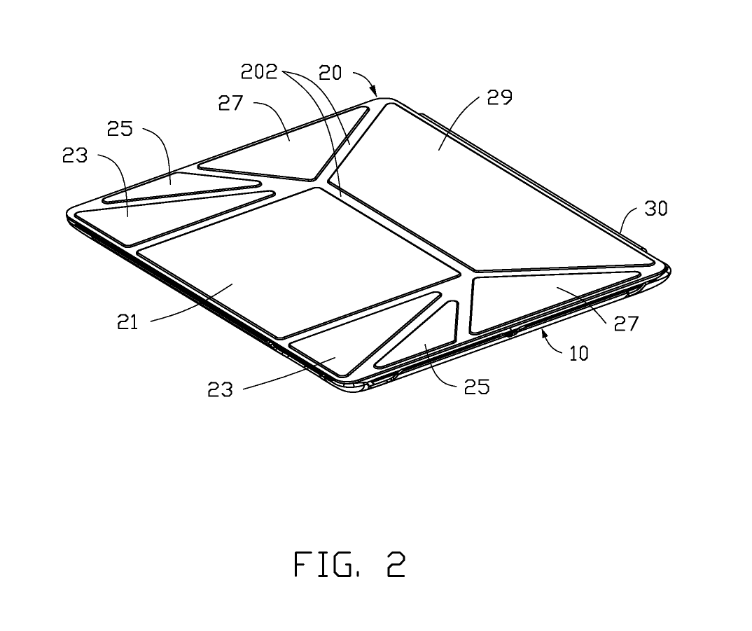

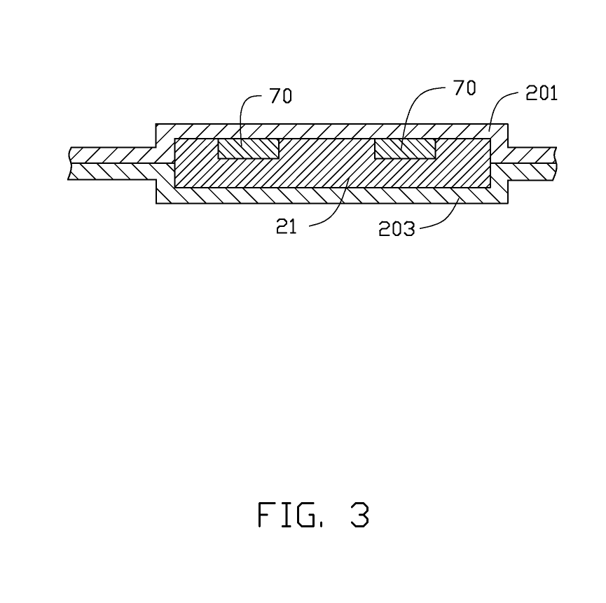

FIGS. 2 and 3 illustrate that the cover portion 20 is substantially rectangular-shaped and comprises a substantially rectangular first reinforcing member 21, two right angle triangle-shaped second reinforcing members 23, symmetrically positioned on opposite sides of the first reinforcing member 21, two isosceles triangle-shaped third reinforcing members 25, symmetrically positioned on opposite sides of the first reinforcing member 21, two obtuse triangle-shaped fourth reinforcing members 27 (which may also be isosceles) positioned on opposite sides of the first reinforcing member 21, and an isosceles trapezoid-shaped fifth reinforcing member 29 positioned adjacent to a side of the first reinforcing member 21. The third reinforcing members 25 also can be obtuse triangles.

Each of the first reinforcing member 21, the second reinforcing members 23, the third reinforcing members 25, the fourth reinforcing member 27, and the fifth reinforcing member 29 comprise a rigid board encapsulated between a first surface layer 201 and a second surface layer 203 of cover portion 20. The first surface layer 201 is an outer surface of the cover portion 20, formed of, for example, leather, and the second surface layer 203 is an inner surface of the cover portion 20, formed of, for example, superfine fiber layer. In areas between reinforcing members, the first surface layer 201 and the second surface layer 203 are connected together to form thinner fold lines 202 between the first reinforcing member 21, the second reinforcing member 23, the third reinforcing member 25, the fourth reinforcing member 27 and the fifth reinforcing member 29. The rigid boards of each of the first reinforcing member 21, the second reinforcing member 23, the third reinforcing member 25, the fourth reinforcing member 27 and the fifth reinforcing member 29 may comprises rigid board materials, such as such as fiberglass, carbon fiber board, cardboard or plastic board. Each of the first reinforcing member 21 and the second reinforcing member 23 comprise a plurality of embedded magnets 70. When the two second reinforcing members 23 are folded to attach the first reinforcing member 21, the magnet 70 of each second reinforcing member 23 is attracted to one of the two magnets 70 of the first reinforcing member 21.

Returning to FIG. 1, the first reinforcing member 21 comprises a pair of parallel first sides 210 and a pair of parallel second sides 212. The first sides 210 are perpendicular to the second sides 212. One first side 210 of the first reinforcing member 21 is located at a middle of a side of the cover portion 20 away from the flexible rubber strip 30. The fifth reinforcing member 29 comprises a first base 290, a second base 292 parallel to the first base 290 and longer than the first base 290, and a pair of non-parallel sides 294 slantingly connected between the first base 290 and the second base 292. Each second reinforcing member 23 comprises a first side 230, a second side 232 and a third side 234. The first side 230 is perpendicular to the second side 232. The third side 234 is connected between the first side 230 and the second side 232. Each third reinforcing member 25 comprises a first side 250, a second side 252 and a third side 254. Each fourth reinforcing member 27 comprises a first side 270, a second side 272 and a third side 274.

The second base 292 of the fifth reinforcing member 29 is adjacent to the flexible rubber strip 30. One of the first sides 210 of the first reinforcing member 21 is beside the first base 290 of the fifth reinforcing member 29. The other first side 210 of the first reinforcing member 21 and the first sides 230 of the two second reinforcing members 23 lie along a straight line. The second side 212 of the first reinforcing member 21 is adjacent and parallel to the second side 232 of the corresponding second reinforcing member 23. The third reinforcing members 25 are respectively located between the two second reinforcing members 23 and the fourth reinforcing members 27. The third side 254 of the third reinforcing members 25 is adjacent and parallel to the third side 234 of two second reinforcing members 23. The second side 252 of the third reinforcing members 25 is adjacent and parallel to the second side 272 of the fourth reinforcing member 27. The fourth reinforcing members 27 are respectively located between the two third reinforcing members 25 and the fifth reinforcing member 29. The second side 272 of the fourth reinforcing member 27 is adjacent and parallel to the second side 252 of two third reinforcing members 25. The third side 274 of the fourth reinforcing member 27 is adjacent and parallel to a side 294 of the fifth reinforcing member 29. And the first side 250 of the third reinforcing member 25 and the first side 270 of the fourth reinforcing member 27 lie along a straight line.

The electronic device 50 is held in the receiving space 105 of the receiving portion 10, and the cover portion 20 can be rotated to cover the receiving portion 10 to protect the electronic device 50.

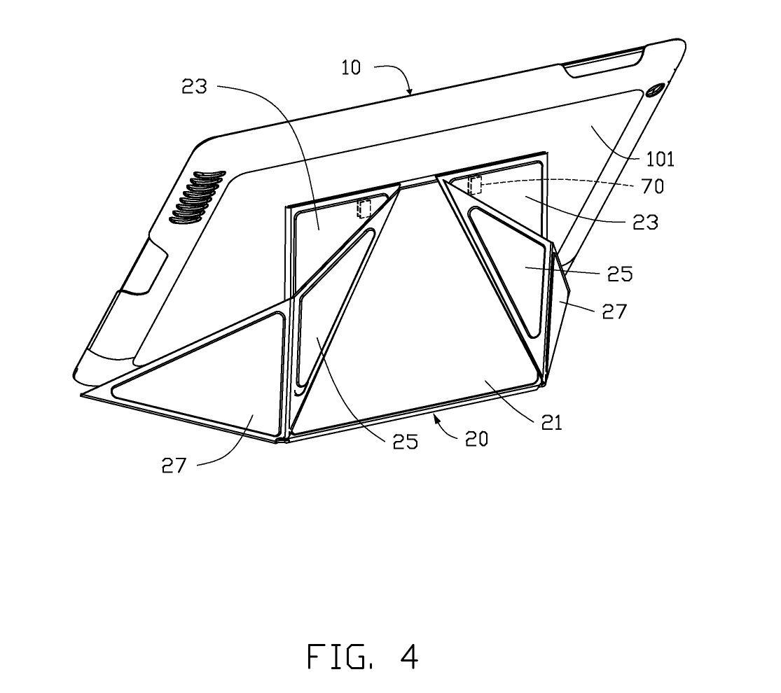

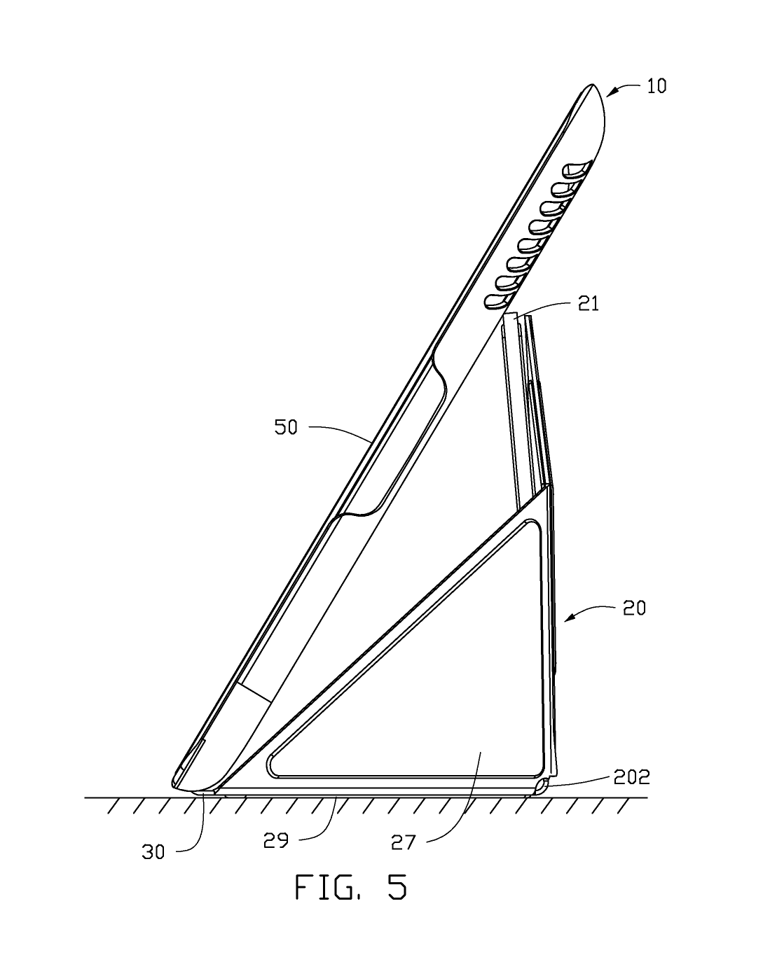

FIGS. 4 and 5 illustrate that electronic device 50 when supported by the cover portion 20 folded in a first configuration. The first reinforcing member 21 is rotated relative to the fifth reinforcing member 29 toward the first surface layer 201 of the cover portion 20, the two second reinforcing members 23 are folded along fold lines until contacting an outer surface of the first reinforcing member 21 and the second reinforcing members 23 are attracted to the first reinforcing member 21 by the magnets 70 embedded therein, and the third reinforcing members 25 are attached to the surface of the second reinforcing members 23 opposite to the first reinforcing member 21, the two fourth reinforcing members 27 are folded along fold lines to be positioned between the first reinforcing member 21 and the fifth reinforcing member 29.

The folded cover portion 20 is rotated toward the receiving portion 10. A perimeter edge of the first side 210 of the first reinforcing member 21 away from the fifth reinforcing member 29 catches a back of the receiving portion 10 to support the receiving portion 10 with the electronic device 50 received in the receiving portion 10. The fifth reinforcing member 29 and a side of the receiving portion 10 adjacent to the flexible rubber strip 30 are supported on a supporting plane, such as a desk. In this embodiment, an angle between the receiving portion 10 and the supporting plane is approximately 60 degrees.

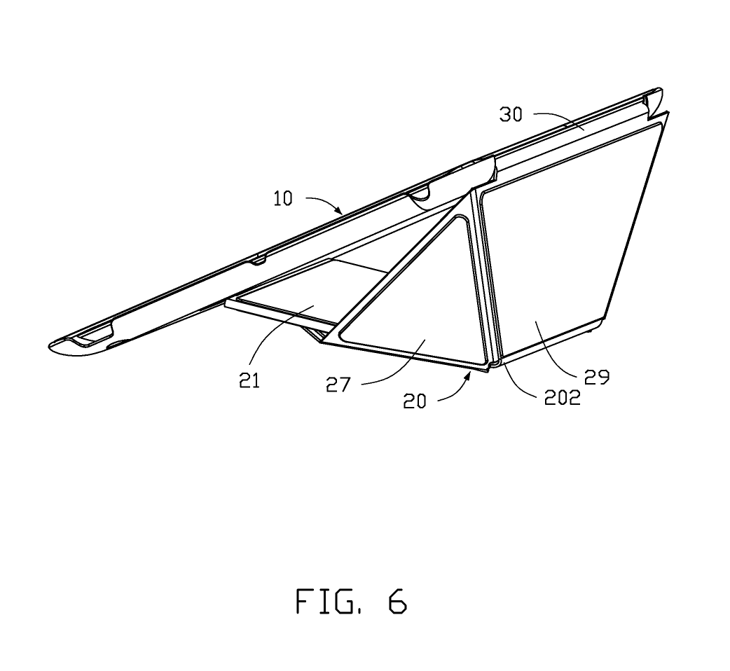

FIG. 6 illustrates the electronic device 50 when supported by the cover portion 20 (see FIG. 5) folded in a second configuration. The first reinforcing member 21 is rotated relative to the fifth reinforcing member 29 toward the first surface layer 201 of the cover portion 20, the two second reinforcing members 23 are folded along fold lines until contacting an outer surface of the first reinforcing member 21 and the second reinforcing members 23 are attracted to the first reinforcing member 21 by the magnets 70 embedded therein, and the third reinforcing members 25 are attached to the surface of the second reinforcing members 23 opposite to the first reinforcing member 21, the two fourth reinforcing members 27 are folded along fold lines to be positioned between the first reinforcing member 21 and the fifth reinforcing member 29. The fold lines 202 between the first reinforcing member 21 and the fourth reinforcing member 27, and a side of the receiving portion 10 away from the flexible rubber strip 30 can be supported on the supporting plane. In this second configuration, the angle between receiving portion 10 and the supporting plane is approximately 25 degrees.

The receiving portion 10 of the protection device 100 can hold the electronic device 50 and the cover portion 20 can be rotated to cover the receiving portion 10 and protect the electronic device 50. And the cover portion 20 can also be folded in two different configurations to support electronic device 50 at different angles.

It is to be understood, however, that even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A protection device comprising:
a receiving portion for receiving an electronic device therein; and
a cover portion pivotally connected to the receiving portion to cover the electronic device, the cover portion comprising a first reinforcing member, two second reinforcing members symmetrically located at two opposite sides of the first reinforcing member, two third reinforcing members symmetrically positioned on opposite sides of the first reinforcing member, two fourth reinforcing members symmetrically located at two opposite sides of the first reinforcing member, and a fifth reinforcing member located between the two fourth reinforcing members;
wherein the two third reinforcing members are respectively located between the two second reinforcing members and the two fourth reinforcing members, the first, second, third, fourth and fifth reinforcing members are foldably connected to each other by fold lines between the reinforcing member; and
wherein the first reinforcing member is folded along a fold line and rotated relative to the fifth reinforcing member and the two second reinforcing members abut an outer surface of the first reinforcing member, the cover portion is rotated to allow the first reinforcing member to abut against a back of the receiving portion.

2. The protection device of claim 1, wherein two third reinforcing members are contacted to a surface of the second reinforcing members opposite to the first reinforcing member, and the two fourth reinforcing members connect between the first reinforcing member and the fifth reinforcing member.

3. The protection device of claim 1, wherein the receiving portion comprises a base plate and a peripheral edge extending from edges of the base plate, the base plate and the peripheral edge form a receiving space for holding the electronic device.

4. The protection device of claim 1, wherein the cover portion is connected to the receiving portion through a flexible rubber strip.

5. The protection device of claim 4, wherein the first reinforcing member is rectangular and comprises a pair of first sides and a pair of second sides perpendicular to the first sides, one first side of the first reinforcing member is located at a middle of a side of the cover away from the flexible rubber strip, the fifth reinforcing member is isosceles trapezoid and comprises a first base, a second base parallel to the first base and longer than the first base and two sides slantingly connected between the first base and the second base, the second base of the fifth reinforcing member is located at a side of the cover adjacent to the flexible rubber strip, the first base of the fifth reinforcing member is adjacent and parallel to one first side of the first reinforcing member.

6. The protection device of claim 5, wherein the second reinforcing member is right angle triangle, the third reinforcing member is isosceles triangle, and the fourth reinforcing member is obtuse triangle, the third reinforcing member also can be obtuse triangle.

7. The protection device of claim 6, wherein the second reinforcing member comprises a first side, a second side and a third side, the first side of the second reinforcing member is perpendicular to the second side of the second reinforcing member, each third reinforcing member comprises a first side, a second side and a third side, each fourth reinforcing member comprises a first side, a second side and a third side.

8. The protection device of claim 7, wherein one first side of the first reinforcing member and the first side of the second reinforcing member lie along a straight line, the second side of the first reinforcing member is adjacent and parallel to the second side of the second reinforcing member, the third side of the third reinforcing members is adjacent and parallel to the third side of two second reinforcing members, the second side of the third reinforcing members is adjacent and parallel to the second side of the fourth reinforcing member, the second side of the fourth reinforcing member is adjacent and parallel to the second side of two third reinforcing members, the third side of the fourth reinforcing member is adjacent and parallel to a side of the fifth reinforcing member, and the first side of the third reinforcing member and the first side of the fourth reinforcing member lie along a straight line.

9. The protection device of claim 1, wherein the first reinforcing member and the two second reinforcing members comprise a plurality of magnets embedded therein for attracting the first reinforcing member and the second reinforcing members.

10. The protection device of claim 1, wherein the first, second, third, fourth and fifth reinforcing members comprise rigid boards.

11. The protection device of claim 10, wherein the rigid boards of the first, second, third, fourth and fifth reinforcing members are encapsulated between a first surface layer and a second surface layer of the cover portion, the first surface layer is an outer surface of the cover portion, and the second surface layer is an inner surface of the cover portion, in areas between reinforcing members, the first surface layer and the second surface layer are connected together to form fold lines between the first, second, third, fourth and fifth reinforcing members.

12. A cover comprising:
a first reinforcing member, two second reinforcing members symmetrically located at two opposite sides of the first reinforcing member, two third reinforcing members symmetrically located at two opposite sides of the first reinforcing member, two fourth reinforcing members symmetrically positioned on opposite sides of the first reinforcing member, and a fifth reinforcing member located between the two fourth reinforcing members;
wherein the two third reinforcing members are respectively located between the two second reinforcing members and the two fourth reinforcing members, the first, second, third, fourth and fifth reinforcing members are foldably connected to each other by fold lines between the reinforcing members; and
wherein the first reinforcing member is folded along a fold line relative to the fifth reinforcing member and the two second reinforcing members are attached to the first reinforcing member.

13. The cover of claim 12, wherein the first reinforcing member is rectangular and comprises a pair of first sides and a pair of second sides perpendicular to the first sides, one first side of the first reinforcing member is located at a middle of a first side of the cover, the fifth reinforcing member is isosceles trapezoid and comprises a first base, a second base parallel to the first base and longer than the first base and two sides slantingly connected between the first base and the second base, the second base of the fifth reinforcing member is located at a second side of the cover, the first base of the fifth reinforcing member is adjacent and parallel to one first side of the first reinforcing member.

14. The cover of claim 12, wherein the second reinforcing member is right angle triangle, the third reinforcing member is isosceles triangle, and the fourth reinforcing member is obtuse triangle, the second reinforcing member comprises a first side, a second side and a third side, the first side of the second reinforcing member is perpendicular to the second side of the second reinforcing member, each third reinforcing member comprises a first side, a second side and a third side, each fourth reinforcing member comprises a first side, a second side and a third side.

15. The cover of claim 14, wherein one first side of the first reinforcing member and the first side of the second reinforcing member lie along a straight line, the second side of the first reinforcing member is adjacent and parallel to the second side of the second reinforcing member, the third side of the third reinforcing members is adjacent and parallel to the third side of two second reinforcing members, the second side of the third reinforcing members is adjacent and parallel to the second side of the fourth reinforcing member, the second side of the fourth reinforcing member is adjacent and parallel to the second side of two third reinforcing members, the third side of the fourth reinforcing member is adjacent and parallel to a side of the fifth reinforcing member, and the first side of the third reinforcing member and the first side of the fourth reinforcing member lie along a straight line.

16. The cover of claim 12, wherein the first reinforcing member and the two second reinforcing members comprise a plurality of magnets embedded therein for attracting the first reinforcing member and the second reinforcing members.

17. The cover of claim 12, wherein the first, second, third, fourth and fifth reinforcing members comprise rigid boards.

18. The cover of claim 12, wherein the rigid boards of the first, second, third, fourth and fifth reinforcing members are encapsulated between a first surface layer and a second surface layer of the cover portion, the first surface layer is an outer surface of the cover portion, and the second surface layer is an inner surface of the cover portion, in areas between reinforcing members, the first surface layer and the second surface layer are connected together to form fold lines between the first, second, third, fourth and fifth reinforcing members.
